(19) United States
(12) Patent Application Publication
(10) Pub. No.: US 2010/0163985 A1
(43) Pub. Date: Jul. 1, 2010

(54) SEMICONDUCTOR AND METHOD FOR MANUFACTURING THE SAME

(76) Inventor: Sung-Wook Kim, Bupyeong-gu (KR)

Correspondence Address: SHERR & VAUGHN, PLLC, 620 HERNDON PARKWAY, SUITE 320, HERNDON, VA, 20170, US

(21) Appl. No.: 12/641,112

(22) Filed: Dec. 17, 2009

(30) Foreign Application Priority Data
Dec. 30, 2008 (KR) 10-2008-0137496

(51) Int. Cl. H01L 29/78; H01L 21/336

(52) U.S. Cl. 257/339; 438/286; 257/E29.256; 257/E21.417

(57) ABSTRACT

A semiconductor includes a high voltage region formed in a substrate, first and second drift regions formed in the high voltage region, an isolation layer in the high voltage region, a gate formed on and/or over the first and second drift regions, and a drain and a source formed in the first drift region and the second drift region.

### CROSS-REFERENCE TO RELATED APPLICATION

The present application claims priority under 35 U.S.C. §119 to Korean Patent Application No. 10-2008-0137496 (filed Dec. 30), 2008, which is hereby incorporated by reference in its entirety.

### BACKGROUND

Since a high-voltage asymmetric MOS transistor includes a source region in the form of a logic junction, the MOS transistor is limited for adaptation to a serial transistor, or a level shift circuit of a source driver IC or a gate driver IC if the source region and a bulk region of the MOS transistor are not subject to the same potential.

If a symmetric transistor is employed in order to overcome such a problem, a transistor pitch is increased in a length direction, so that a chip size may be increased.

### SUMMARY

Embodiments relate to a semiconductor and a method of manufacturing the same which is available regardless of potential between a source region and a bulk region even if a high voltage is applied to the semiconductor.

Embodiments relate to a semiconductor and a method of manufacturing the same that reduces a chip size due to the reduction of a transistor pitch in a length direction.

In accordance with embodiments, a semiconductor can include at least one of the following: a high voltage region formed in a substrate, first and second drift regions formed in the high voltage region, an isolation layer formed in the high voltage region, a gate formed on and/or over the first and second drift regions, and a drain and a source formed in the first drift region and the second drift region.

In accordance with embodiments, a semiconductor can include at least one of the following: a high voltage region formed in a substrate; a first drift region formed in the high voltage region; a second drift region formed in the high voltage region spaced apart from the first drift region; a plurality of isolation layers formed over the substrate in the high voltage region; a gate oxide layer formed between an adjacent pair of isolation layers; a gate formed over the substrate and overlapping the first drift region and the second drift region, a portion of the gate being formed directly on the gate oxide layer and another portion of the gate being formed directly on one of the isolation layers; a drain formed in the first drift region; and a source formed in the first drift region and the second drift region.

In accordance with embodiments, a method for manufacturing a semiconductor can include at least one of the following: forming a high voltage region in a substrate, forming first and second drift regions in the high voltage region, forming an isolation layer in the high voltage region, forming a gate on and/or over the first and second drift regions, and then forming a drain and a source in the first drift region and the second drift region.

### DRAWINGS

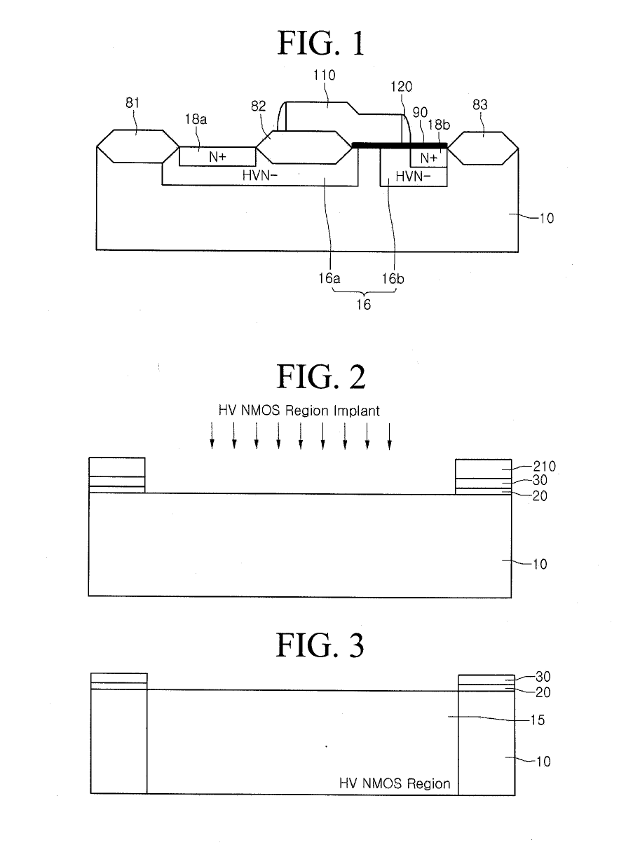

Example FIGS. 1 to 9 illustrate a semiconductor and a method for manufacturing a semiconductor in accordance with embodiments.

### EMBODIMENTS

Hereinafter, a semiconductor and a method for manufacturing the same in accordance with embodiments will be described with reference to accompanying drawings.

In the description of embodiments, it will be understood that when a layer (or film) is referred to as being “on” another layer or substrate, it can be directly on another layer or substrate, or intervening layers may also be present. Further, it will be understood that when a layer is referred to as being “under” another layer, it can be directly under another layer, and one or more intervening layers may also be present. In addition, it will also be understood that when a layer is referred to as being “between” two layers, it can be the only layer between the two layers, or one or more intervening layers may also be present.

Example FIG. 1 illustrates a sectional view of a semiconductor in accordance with embodiments.

As illustrated in example FIG. 1, the semiconductor includes high voltage region 15 formed on and/or over substrate 10. First and second drift regions 16a and 16b formed spaced apart in high voltage region 15. A plurality of isolation layers 81, 82, and 83 are formed in high voltage region 15. Gate 110 is formed on and/or over first and second drift regions 16a and 16b so as to partially overlap first and second drift regions 16a and 16b, respectively. Gate 110 may be formed to directly contact isolation layer 82. Drain 18a and source 18b are formed in first and second drift regions 16a and 16b, respectively.

In accordance with embodiments, the semiconductor and method for manufacturing the same includes a source region of a high voltage asymmetric transistor which forms an HV junction through an HVN−[NDRIFT] ion implant process similarly to a drain region. Accordingly, even if a high voltage is applied to the transistor, the transistor can be used regardless of potential between the source region and a bulk region. Therefore, the transistor can be adapted to a serial transistor or a level shift stage of a source driver IC or a gate driver IC in an LCD driver IC (LDI) as well as a typical high voltage transistor, thereby ensuring effective characteristics.

In addition, in according with embodiments, a chip size is reduced due to the reduction of a transistor pitch, so that the manufacturing cost can be reduced due to the increase of a net die in a wafer thereby contributing to the sales of the manufacturing company and ensuring the competitiveness thereof.

Hereinafter, a method of manufacturing the semiconductor in accordance with embodiments will be described with reference to example FIGS. 2 to 9.

As illustrated in example FIG. 2, first and second insulating layers 20 and 30 are formed on and/or over substrate 10. First photoresist 210 is formed on and/or over first and second insulating layers 20 and 30 and the resultant is then etched and subjected to an ion implantation process using first photoresist pattern 210 as a mask to form high voltage region 15 in substrate 10. First insulating layer 20 may be a pad oxide layer and second insulating layer 30 may be a nitride layer, but embodiments are not limited thereto.

The ion implantation process to form high voltage region 15 can include an HV NMOS region implant process, but embodiments are not limited thereto. In this case, the ion implantation process may be performed with respect to a region other than the first insulating layer 20 serving as the pad oxide layer.

As illustrated in example FIG. 3, first photoresist pattern 210 is removed. High voltage region 15 (e.g., an HV NMOS region) may be formed through a thermal diffusion process. In order to reduce overall manufacturing time, a thermal diffusion process of high voltage region 15 may be additionally performed when a diffusion process is performed with respect to drift region (16HVN−) 16 after an ion implantation process has been performed with respect to drift region (16HVN−) 16.

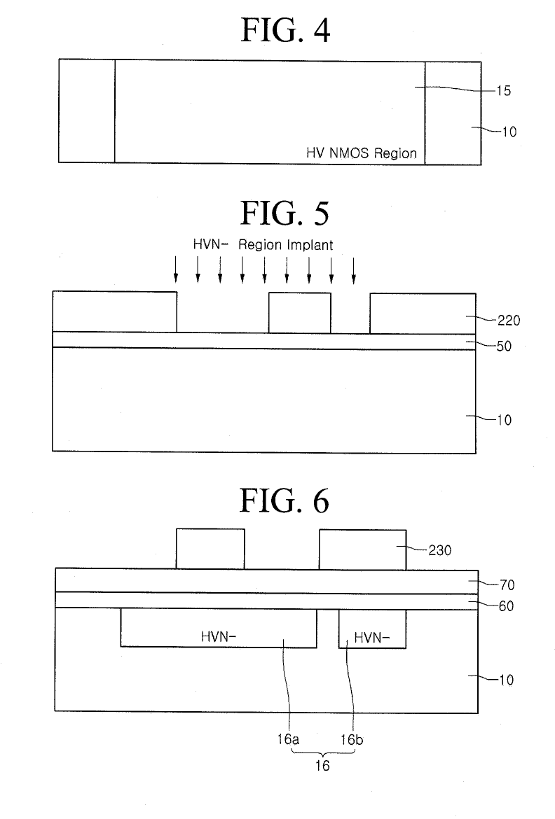

As illustrated in example FIG. 4, first and second insulating layers 20 and 30 are then removed. For example, the pad oxide layer and the nitride layer can be removed through an H₃PO₄ dip process. Alternatively, pad oxide layer which serves as first insulating layer 20 may remain.

As illustrated in example FIG. 5, another ion implantation process can be performed to form first and second drift regions 16a and 16b in high voltage region 15. For example, after third insulating layer 50 has been formed, second photoresist pattern 220 may be formed to open or otherwise expose first and second drift regions 16a and 16b and then the HVN-region implant process may be performed. Drift region 16 includes first and second drift regions 16a and 16b formed in the drain and source regions of substrate 10, respectively. For example, after third insulating layer 50 has been deposited as a buffer oxide layer, a 16HVN−[NDRIFT] region may be defined and an ion implantation process may be performed using second photoresist pattern 220 as a mask. In accordance with embodiments, the buffer oxide layer, which is third insulating layer 50, may not be deposited if the pad oxide layer, which is first insulating layer 20, is left in the process of example FIG. 4.

As illustrated in example FIG. 6, after second photoresist pattern 220 has been removed, the thermal diffusion process is performed to form drift region 16. Thereafter, photoresist pattern 230 is formed to form isolation layer 80 in high voltage region 15.

For example, the 16HVN−[NDRIFT] region including first and second drift regions 16a and 16b is formed through a thermal diffusion process after second photoresist pattern 220 has been removed. In this case, the diffusion process for HV NMOS well 15 of example FIG. 3 can be additionally performed. Thereafter, after the buffer oxide layer serving as third insulating layer 50 has been removed, fourth and fifth insulating layers 60 and 70 are formed in order to form an active region. Thereafter, an isolation region is opened by third photoresist pattern 230, thereby performing a process of forming the active region. For example, fourth insulating layer 60 is formed by using an oxide layer, and fifth insulating layer 70 may be formed by using a nitride layer, but embodiments are not limited thereto.

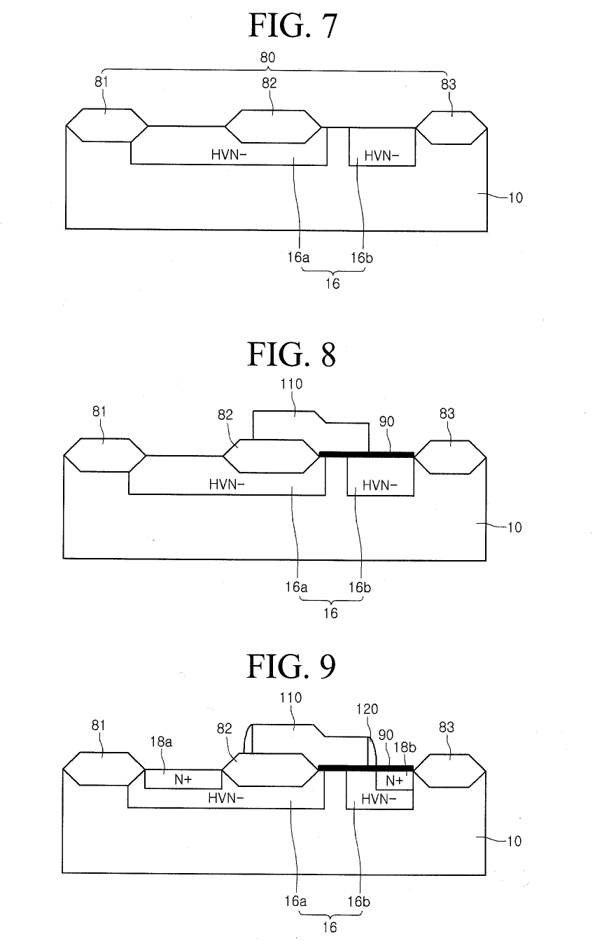

As illustrated in example FIG. 7, thereafter, isolation layer 80 including first to third isolation layers 81, 82, and 83 is formed. Second isolation layer 82 may be formed in first drift region 16a. For example, after third photoresist pattern 230 has been removed, the active region is isolated through a field oxidation process, and then fourth and fifth insulating layers 60 and 70 can be removed through a H₃PO₄ dip process. Isolation layer 80 can be formed through a shallow trench isolation (STI) process to isolate the active region.

As illustrated in example FIG. 8, gate 110 is formed in first and second drift regions 16a and 16b. After performing a second buffer oxidation process for an ion implant process thereafter, a logic well implant process to form a logic device, a logic & high voltage Tr Vt implant process for a high-voltage transistor, and a HV & LV gate oxidation process, a polygate is deposited to define. Then, gate oxide layer 90 and high voltage gate 110 are formed. Gate 110 may be formed on and/or over second isolation layer 82 in first drift region 16a.

As illustrated in example FIG. 9, drain 18a and source 18b are formed in first and second drift regions 16a and 16b, respectively. For example, after a gate reoxidation process and a process of forming sidewall spacer 120 have been performed, an N+ region is defined through a photo-process and an ion implant process, thereby forming source 18b and drain 18a. Thereafter, a metal interconnection process can be performed.

In accordance with embodiments, a semiconductor and method for manufacturing the same includes a source region of the high voltage asymmetric transistor which forms the HV junction through the HVN−[NDRIFT] ion implant process similarly to the drain region. Accordingly, even if a high voltage is applied to the transistor, the transistor can be used regardless of potential between the source region and the bulk region. Therefore, the transistor can be adapted to a serial transistor or a level shift stage of a source driver IC or a gate driver IC in an LCD driver IC (LDI) as well as a typical high voltage transistor, thereby ensuring effective characteristics.

In addition, in accordance with embodiments, a chip size is reduced due to the reduction of a transistor pitch, so that the manufacturing cost can be reduced due to the increase of a net die in a wafer, thereby contributing to the sales of the manufacturing company and ensuring the competitiveness thereof.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a high voltage region formed in a substrate;
first and second drift regions formed in the high voltage region;
an isolation layer formed in the high voltage region;
a gate formed over the first and second drift regions; and
a drain and a source formed in the first drift region and the second drift region, respectively.

2. The apparatus of claim 1, wherein the high voltage region in the substrate comprises a first conductive type ion implantation region.

3. The apparatus of claim 1, wherein the first and second drift regions in the high voltage region are formed in a drain region and a source region of the substrate, respectively.

4. The apparatus of claim 1, wherein the isolation layer is also formed in the first drift region.

5. The apparatus of claim 1, wherein the gate is also formed directly on the isolation layer provided in the first drift region.

6. The apparatus of claim 1, wherein the apparatus comprises a semiconductor.

7. An apparatus comprising:
a high voltage region formed in a substrate;
a first drift region formed in the high voltage region;
a second drift region formed in the high voltage region spaced apart from the first drift region;
a plurality of isolation layers formed over the substrate in the high voltage region;
a gate oxide layer formed between an adjacent pair of isolation layers;
a gate formed over the substrate and overlapping the first drift region and the second drift region, a portion of the gate being formed directly on the gate oxide layer and another portion of the gate being formed directly on one of the isolation layers;
a drain formed in the first drift region; and
a source formed in the first drift region and the second drift region.

8. The apparatus of claim 7, further comprising spacers formed over sidewalls of the gate.

9. The apparatus of claim 8, wherein one of the spacers is formed directly on one of the isolation layers and another spacer is formed directly on the gate oxide layer.

10. The apparatus of claim 7, wherein the apparatus comprises a semiconductor.

11. A method comprising:
forming a high voltage region in a substrate;
forming first and second drift regions in the high voltage region;
forming an isolation layer in the high voltage region;
forming a gate over the first and second drift regions; and then
forming a drain and a source in the first drift region and the second drift region, respectively.

12. The method of claim 11, wherein forming the high voltage region comprises:
forming a first pattern exposing a portion of the substrate; and then
forming a first conductive ion implantation region by implanting first conductive ions in the region of the substrate using the first pattern as a mask.

13. The method of claim 11, wherein forming the isolation layer in the high voltage region comprises forming an isolation layer in the first drift region.

14. The method of claim 11, wherein forming the gate over the first and second drift regions comprises forming the gate over an isolation layer in the first drift region.

15. The method of claim 11, wherein forming the gate comprises forming the gate directly on the isolation layer provided in the first drift region.

16. The method of claim 11, wherein forming the isolation layer comprises forming a plurality of isolation layers over the substrate in the high voltage region.

17. The method of claim 16, further comprising forming a gate oxide layer between an adjacent pair of the isolation layers.

18. The method of claim 17, wherein forming the gate comprises forming a portion of the gate directly on the gate oxide layer and another portion of the gate being formed directly on one of the isolation layers.

19. The method of claim 11, wherein the drain and the source are formed in the first and second drift regions, respectively.

20. The method of claim 11, wherein the first and second drift regions of the high voltage region are formed in a drain region and a source region of the substrate, respectively.
